(19) United States
(12) Patent Application Publication
(10) Pub. No.: US 2007/0207625 A1
(43) Pub. Date: Sep. 6, 2007

(54) Semiconductor processing apparatus with multiple exhaust paths

(76) Inventors: Ravinder Aggarwal, Gilbert, AZ (US); Jeroen Stoutjesdijk, Scottsdale, AZ (US)

Correspondence Address: KNOBBE, MARTENS, OLSEN & BEAR LLP, 2040 MAIN STREET, FOURTEENTH FLOOR, IRVINE, CA, 92614, US

(21) Appl. No.: 11/368,951

(22) Filed: Mar. 6, 2006

(51) Int. Cl. H01L 21/31

(52) U.S. Cl. 438/758

(57) ABSTRACT

An improved exhaust conductance system for a semiconductor process apparatus includes at least two parallel exhaust paths and a valve apparatus for controlling flow to the exhaust paths. The valve apparatus prevents the flow of process gases through one or more of the exhaust paths but simultaneously allows the flow of process gases through at least one other exhaust path. The inactive exhaust paths can be purged or cleaned without resulting in processing downtime to the system.

### BACKGROUND OF THE INVENTION

1. Field of the Invention

The present invention relates generally to the field of semiconductor processing and more specifically to an exhaust conductance system for a semiconductor processing apparatus.

2. Description of the Related Art

Semiconductor processing relates generally to adding layers to, and removing layers from, a semiconductor substrate. Processes that add layers to a substrate include chemical vapor deposition (CVD), atomic layer deposition (ALD), physical vapor deposition (PVD), sputtering, and photolithography. Processes that remove layers from a substrate include wet and dry etching. Many of these processes require exposing the substrate to chemicals within a process chamber, and then carrying away unreacted chemicals and process byproducts through an exhaust conductance path.

In the context of semiconductor fabrication, the substrate typically is a wafer approximately 50 to 300 millimeters in diameter, with sizes up to 450 mm expected in the future. As an example of processing in a semiconductor process chamber, a typical CVD system is described. A wafer handler places one or more wafers into a process chamber through a gate valve, which is then closed. A process gas, which contains particle-generating compounds to be deposited onto the wafers, is introduced into the process chamber through a separate passage. As the process gas passes over the wafer or wafers, a chemical layer is deposited on the surface of the wafers as a result of a reaction or decomposition.

After passing through the process chamber, the process gas exits the chamber through an exhaust conductance path. The exhaust conductance path typically leads to a scrubber or other device that treats the effluent gas for proper disposal. As the process gas travels through the exhaust conductance path towards the scrubber, some chemical compounds in the process gas adhere to the walls of the conductance path, thus contaminating the system.

Upon completion of each deposition process, a purging gas is introduced into the process chamber in order to expel the process gas from the chamber. Like the process gas, the purging gas travels through the process chamber and exits through the exhaust conductance path.

After the process chamber has been purged and isolated from the exhaust conductance path, the gate valve is opened and the processed wafer or wafers are removed and replaced with an unprocessed wafer or unprocessed wafers. The gate valve is then closed, and a new cycle of the process commences.

FIG. 1 shows a conventional exhaust assembly 100. A semiconductor process chamber 105 includes an exhaust outlet port 190. Gases flowing out of the exhaust outlet port 190 flow through the exhaust assembly 120. If the exhaust assembly 120 is a reduced pressure stack (“RP stack”), it will typically include a coarse flow rate adjustment valve 124 in parallel with a fine flow rate adjustment valve 122 (the flow rate adjustment valves 122 and 124 are together referred to herein as a “flow rate adjustment valve assembly”), a pressure control valve 126, and an isolation valve 128. Gases then flow through a pump 130 to a scrubber 140.

The exhaust assembly 120, including the illustrated conductance lines, must be periodically cleaned because the deposit buildup may contaminate the process chamber 105, because the deposits may be flammable as a result of the chemistries used during processing, and because blockage of the exhaust assembly 120 may impede processing. Excess deposit buildup resulting from certain chemistries leads to a dangerous condition where the exhaust assembly 120 becomes prone to “flash,” or a small explosion, when exposed to oxygen.

Although processing has been described for a CVD process, the teachings of this application may be applied to other semiconductor processes such as ALD, PVD, sputtering, photolithography, and etching. For example, in a photolithography process, photoresist may be the deposited species that needs to be periodically cleaned from the exhaust conductance path.

Cleaning the exhaust conductance path is desirable when semiconductor process chamber 105 is a CVD chamber and the process gases comprise species used for epitaxy, which typically requires cleaning at least every 200 hours. In some embodiments, cleaning may be required more frequently, for example at least every 150 hours. The ideal duration between cleanings may depend on a number of variables including process gases used, dopant concentration, temperature, pressure, process flowrates and durations, process byproducts, exhaust assembly material, post-process purge flowrates and durations, process chamber usage, etc. During the cleaning, semiconductor process chamber 105 is unable to process wafers because there is no exhaust conductance path that process gases may flow through, and thus the apparatus 100 experiences downtime. Wafer throughput during this downtime is zero.

As described above, purge gas is typically directed through semiconductor process chamber 105 and exhaust assembly 120 after each process cycle so that process gases do not remain in process chamber 105 when the wafer or wafers are removed. A purge may also be performed between processes that use different types of process gases (e.g., two types of deposition gases or deposition gases and etching gases). In addition, the exhaust assembly 120 is preferably thoroughly purged before cleaning the deposits in order to help alleviate problems such as flash. This “pre-clean” purging is different from the post-process purging because the duration is longer and because it is performed in order to minimize the flashable deposits rather than to expel process gases. During pre-clean purging, the semiconductor process chamber 105 cannot process wafers because process gases cannot flow out of process chamber 105 through exhaust assembly 120, as pre-clean purging gases may enter the process chamber 105. The process chamber 105 cannot process while the exhaust assembly 120 is being cleaned or while the exhaust assembly 120 is being pre-clean purged. Thus, a pre-clean purge increases the amount of downtime and decreases throughput. Alternatively, the pre-clean purge may be truncated or skipped in order to mitigate downtime, leading to a potentially dangerous situation in which exhaust assembly 120 is not adequately purged prior to cleaning. Inadequately purged exhaust assemblies are more prone to flash than adequately purged exhaust assemblies because the amount of flash-prone material removed prior to maintenance is reduced.

### SUMMARY OF THE INVENTION

In one aspect, the present invention provides an apparatus for semiconductor processing comprising a semiconductor process chamber, a first exhaust assembly, and a second exhaust assembly. The first and second exhaust assemblies are in communication with and downstream of the semiconductor process chamber. The second exhaust assembly is in parallel with the first exhaust assembly.

In another aspect, the present invention provides a method of processing workpieces in a process chamber. The method comprises flowing a process gas into the process chamber and enabling the process gas to exit the process chamber and enter and flow through a first exhaust assembly for a first duration. The first exhaust assembly is in communication with and downstream of the process chamber. The method further comprises preventing the process gas from entering and flowing through a second exhaust assembly during the first duration. The second exhaust assembly is in communication with and downstream of the process chamber, and is in parallel with the first exhaust assembly. The method further comprises preventing the process gas from entering and flowing through the first exhaust assembly and enabling the process gas to exit the process chamber and enter and flow through the second exhaust assembly during a second duration. The second duration is after the first duration.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

These and other features, aspects, and advantages of the invention disclosed herein are described below with reference to the drawings of preferred embodiments, which are intended to illustrate and not to limit the invention. The drawings comprise eight figures in which:

FIG. 1 illustrates an apparatus with a conventional exhaust assembly.

FIG. 2A illustrates an embodiment of an apparatus with multiple exhaust paths.

FIG. 2B illustrates another embodiment of an apparatus with multiple exhaust paths.

FIG. 2C illustrates yet another embodiment of an apparatus with multiple exhaust paths.

FIG. 2D illustrates still another embodiment of an apparatus with multiple exhaust paths.

FIG. 2E illustrates yet still another embodiment of an apparatus with multiple exhaust paths.

FIG. 2F illustrates a further embodiment of an apparatus with multiple exhaust paths.

FIG. 3 illustrates an embodiment of an apparatus with multiple exhaust paths and a purge gas assembly.

### DETAILED DESCRIPTION OF THE PREFERRED EMBODIMENTS

Although certain preferred embodiments and examples are disclosed below, it will be understood by those in the art that the invention extends beyond the specifically disclosed embodiments and/or uses of the invention and obvious modifications and equivalents thereof. Thus, it is intended that the scope of the invention herein disclosed should not be limited by the particular disclosed embodiments described below.

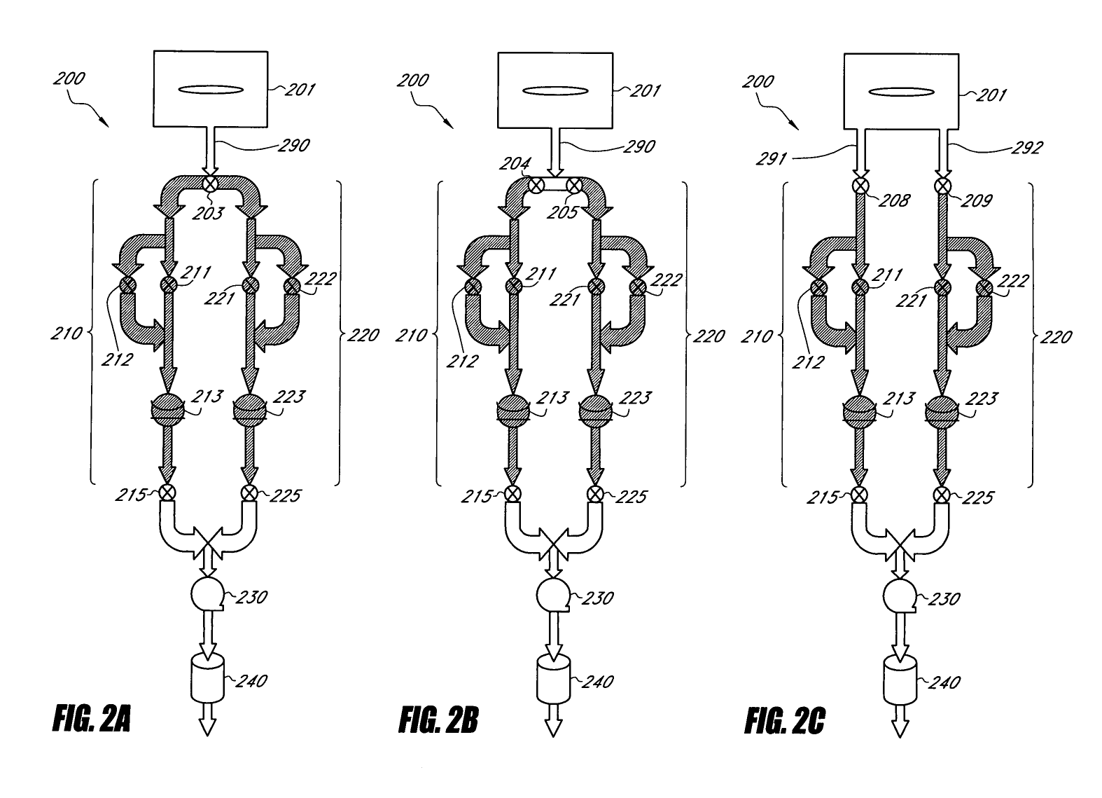

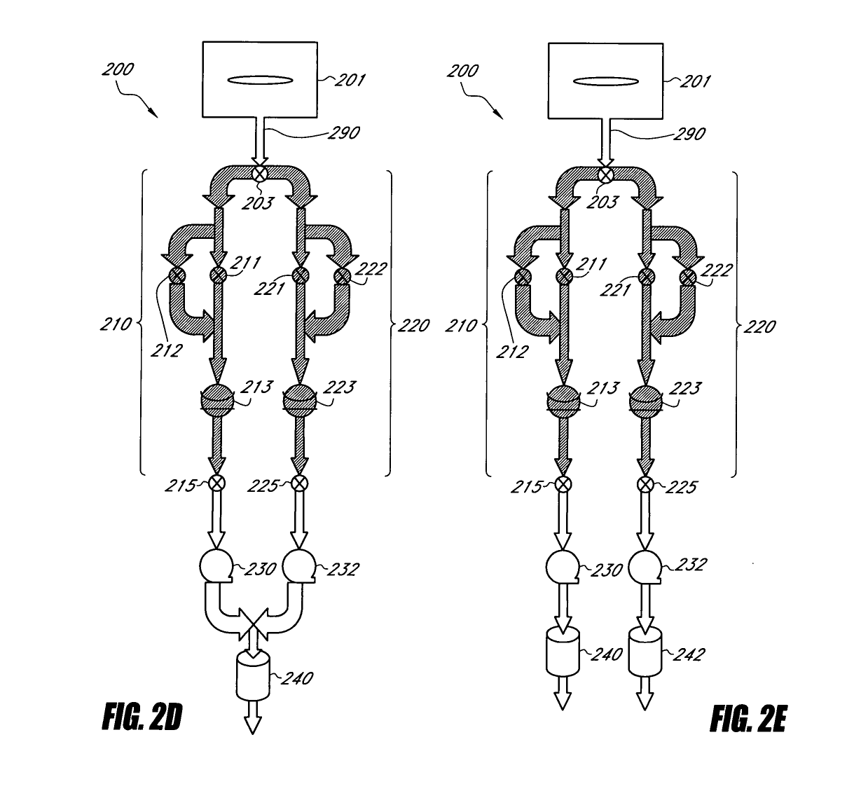

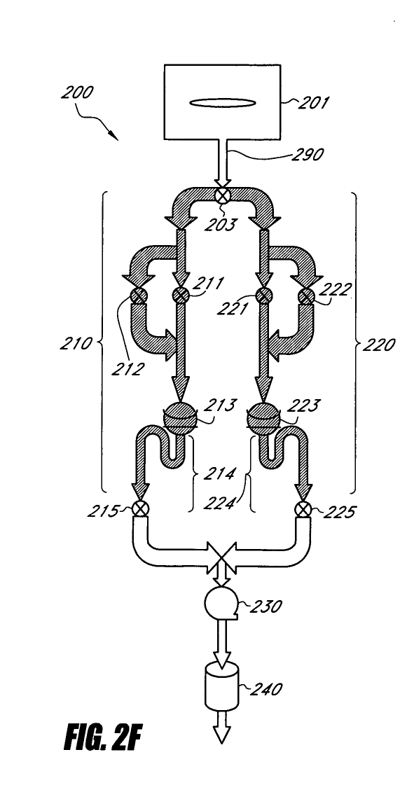

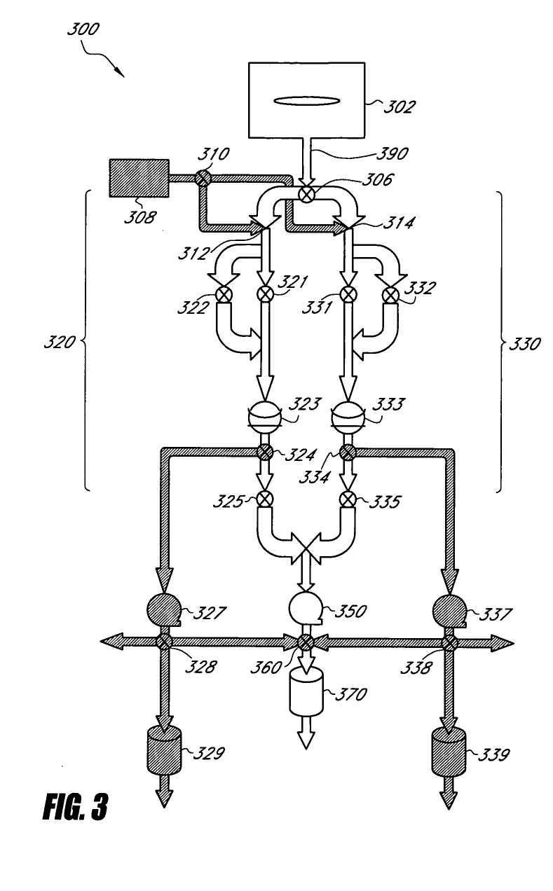

FIG. 2A illustrates an embodiment of an apparatus with multiple exhaust paths. The semiconductor process chamber 201 has an exhaust outlet port 290. The exhaust outlet port 290 may be a flange, manifold, aperture, or other outlet structure. In a preferred embodiment, semiconductor process chamber 201 is a CVD chamber and the process gases used are those suitable for epitaxial growth, which are well-known in the art. Because epitaxy typically takes place at low pressure, the exhaust assemblies 210, 220 are preferably RP stacks. However, atmospheric (comparatively higher pressure) exhaust assemblies may also be used, typically in apparatuses in which processes are performed at or near atmospheric pressure.

The exhaust assemblies 210, 220 may be different from each other. For example, an RP stack may be in parallel with an atmospheric exhaust. Such an apparatus would be suitable for conducting epitaxial deposition (or other low pressure processes) during one duration and a higher pressure process during another duration.

Gases flow out the semiconductor process chamber 201 through the exhaust outlet port 290. The apparatus 200 is configured so that gases flowing out of the exhaust outlet port 290 can flow through different exhaust assemblies in parallel. FIGS. 2A through 2F and 3 depict apparatuses with two exhaust assemblies in parallel. Dual exhaust assemblies are a preferred embodiment (compared to embodiments with more than two exhaust assemblies) because fabrication equipment has limited physical space in which to place exhaust assemblies. However, the present invention is not limited to embodiments with two exhaust assemblies and can include more than two exhaust assemblies in parallel.

Those of ordinary skill in the art will appreciate that there are many possible ways to route gases from a semiconductor process chamber to two or more exhaust assemblies. For example, in FIG. 2A, a valve 203 is interposed between semiconductor process chamber 201 and two parallel exhaust assemblies 210 and 220. The valve 203 preferably directs exhaust gases through either the first exhaust assembly 210 or the second exhaust assembly 220. In one embodiment, the valve 203 comprises a three-way valve. As used herein, the term “valve” is to be given its broadest ordinary meaning, including, but not limited to, a structure that closes a passage. The valves may include, for example, ball valves, butterfly valves, gate valves, globe valves, solenoid valves, and other suitable valves, and may be operated manually or by a machine. Each of the valves described herein may comprise an isolation valve. As used herein, the term “isolation valve” is to be given its broadest ordinary meaning, including, but not limited to, a structure that completely closes a passage.

In another embodiment, as illustrated in FIG. 2B, the exhaust assembly 210 comprises a valve 204 and the exhaust assembly 220 comprises a valve 205. The valves 204 and 205 may work together or separately to route gases through the desired exhaust assembly. For example, each valve 204, 205 may work independently to restrict or to allow gases to flow through its respective exhaust assembly 210, 220, or the valves 204, 205 may depend on the state of the other valve such that each valve may open only while the other valve is closed.

FIG. 2C shows an embodiment with two exhaust outlet ports 291 and 292. The exhaust outlet port 291 leads to the exhaust assembly 210 and the exhaust outlet port 292 leads to the exhaust assembly 220. In the illustrated embodiment, the exhaust assemblies 210 and 220 include valves 208 and 209, respectively, which control the flow of the process gases from the process chamber 201 to the exhaust assemblies 210, 220. The valves 208 and 209 may work together or separately to route gases through the desired exhaust assembly or assemblies. For example, each valve 208, 209 may work independently to restrict or to allow gases to flow through its respective exhaust assembly 210, 220, or the valves 208, 209 may depend on the state of the other valve such that one valve may open only while the other valve is closed.

In a preferred embodiment of the apparatus 200 depicted in FIG. 2A, gases flow through the exhaust assembly 210 while the valve 203 prevents the gases from flowing from the semiconductor process chamber 201 through the exhaust assembly 220. In order to ensure that the exhaust assembly 210 is isolated from the exhaust assembly 220, the isolation valve 225 should be closed.

Once directed solely to the exhaust assembly 210, the gases flow through the coarse flow rate adjustment valve 211 and the fine flow rate adjustment valve 212 (together a flow rate adjustment valve assembly), then through the pressure control valve 213, and then through the isolation valve 215. The coarse flow rate adjustment valve 211 and the fine flow rate adjustment valve 212 can be used to control the flowrate of gases through the exhaust assembly 210, and the pressure control valve 213 can be used to control the pressure of gases within the process chamber 201. The isolation valve 215 can be any type of valve suitable for allowing and terminating flow through the exhaust assembly 210.

In the embodiment depicted in FIG. 2A, after flowing through the isolation valve 215, the gases flow through a pump 230 and a scrubber 240. In a preferred embodiment, only one pump 230 and one scrubber 240 are used to prepare the gases for proper disposal. However, each exhaust assembly 210, 220 may have a separate pump and/or a separate scrubber, as illustrated in FIGS. 2D and 2E.

In FIG. 2D, gases flowing from the exhaust assembly 210 flow through the pump 230, while gases flowing from the exhaust assembly 220 flow through the pump 232. Alternatively, but not illustrated, the apparatus 200 could be configured so that gas flow from each exhaust assembly can be selectively directed to either pump as desired. For example, the apparatus 200 could direct the flow of gases from the exhaust assembly 210 through the pump 232 or gases from exhaust assembly 220 through pump 230, with an additional valve apparatus provided for pump selection. This type of modification would be appropriate if it is desirable to utilize either pump 230, 232 in conjunction with either exhaust assembly 210, 220, such as if the pumps 230, 232 required cleaning independent of the exhaust assemblies 210, 220.

In FIG. 2E, gases flowing from the exhaust assembly 210 flow through the pump 230 and then through the scrubber 240, while gases flowing from the exhaust assembly 220 flow through the pump 232 and then through the scrubber 242. Alternatively, but not illustrated, the apparatus 200 could be configured so that gas flow from each pump can be selectively directed to either scrubber, as desired. For example, the apparatus 200 could direct the flow of gases from the pump 230 to the scrubber 242 or gases from pump 232 to scrubber 240, with an additional valve apparatus provided for scrubber selection. This type of modification would be appropriate if it is desirable to utilize either scrubber 240, 242 in conjunction with either exhaust assembly 210, 220, such as if the scrubbers 240, 242 were designed to scrub different types of process gases or need to be periodically cleaned without reducing downtime of the process chamber 201. The number of pumps and scrubbers in the apparatus 200 can be selected based on factors such as cost, convenience, uniformity, and physical space available. Skilled artisans will recognize that other embodiments of the invention, including embodiments described herein, can include multiple pumps and/or multiple scrubbers.

FIG. 2F illustrates an embodiment in which the exhaust assemblies 210 and 220 include traps 214 and 224, respectively. Alternatively, but not depicted, only one of the exhaust assemblies could have a trap. Preferably, the trap 214 is a U-shaped condenser pipe located between the pressure control valve 213 and the isolation valve 215, and the trap 224 is a U-shaped condenser pipe located between the pressure control valve 223 and the isolation valve 225. The traps 214, 224 may comprise a filter or other well-known trap assembly.

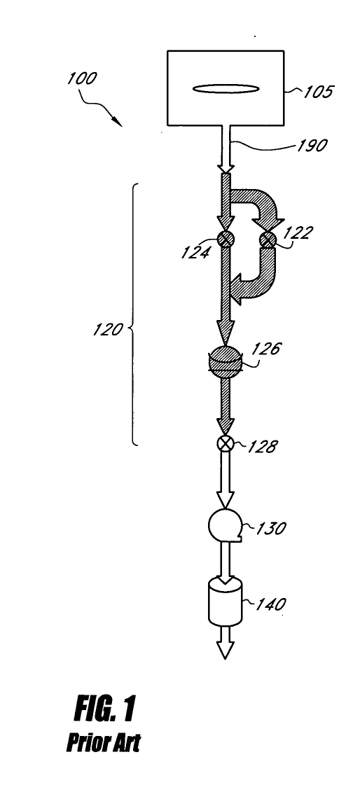

The embodiments illustrated in FIGS. 2A through 2F all allow one exhaust assembly to be isolated from the system while exhaust gases flow through the other exhaust assembly. For example, in FIG. 2A, the valve 203 can be set such that process gases flow only into the exhaust assembly 210, with the isolation valve 225 being closed and the isolation valve 215 being open. When the exhaust assembly 220 is isolated, the semiconductor process chamber 201 can operate similarly to the apparatus 100 depicted in FIG. 1. That is, process gases exiting the semiconductor process chamber 201 only flow through a single exhaust conductance path, the exhaust assembly 210. Because the exhaust assembly 220 is isolated from the apparatus 200, operations (e.g., cleaning) can be conducted on the exhaust assembly 220 without affecting the performance or throughput of the semiconductor process chamber 201. Alternatively, the valve 203 can be set such that process gases flow only into the exhaust assembly 220, with the isolation valve 215 being closed and the isolation valve 225 being open. Because the exhaust assembly 210 is isolated from the apparatus 200, operations can be conducted on the exhaust assembly 210 without affecting the performance or throughput of the semiconductor process chamber 201.

One aspect of the present invention is the recognition that certain problems associated with cleaning the contaminated exhaust assembly can be overcome by providing at least two exhausts in parallel. For example, the apparatus experiences less downtime because one exhaust assembly may be purged and/or cleaned while the process gases are directed from the semiconductor process chamber through another exhaust assembly. Also, while a particular exhaust assembly is not being used, it can be disconnected and optionally removed from the remaining apparatus. Disconnecting an exhaust assembly allows for easier cleaning and also allows the exhaust assembly to be moved to a portion of the fabrication facility more suitable for cleaning. Cleaning an exhaust assembly may comprise replacement of parts. Cleaning can also involve directing purge and/or reactive gases (“pre-clean purge gases”) through the exhaust assembly without disconnecting it from the apparatus.

In certain embodiments, the exhaust assembly 210 is configured to be disconnectable at points near the valve 203 and the isolation valve 215. More preferably, the exhaust assembly 210 is configured to be disconnectable at points as close to the semiconductor process chamber 201 and the isolation valve 215 as the design allows. The exhaust assembly 210 can then be cleaned while the semiconductor process chamber 201 experiences little or no downtime because gases may flow out of the semiconductor process chamber 201 through the exhaust assembly 220. Once the exhaust assembly 210 is cleaned (which may or may not involve disconnecting and reconnecting the exhaust assembly 210), the valve 203 and the isolation valve 215 can be set to allow process gases to flow through the exhaust assembly 210. The procedure can then be repeated to clean the exhaust assembly 220 by setting the valve 203 such that process gases flow only into the exhaust assembly 210 and by closing the isolation valve 225, which isolates the exhaust assembly 220.

As described above, at least two types of purging can be performed in a typical apparatus. The first type of purging, typically performed after each process cycle or step, involves directing inert gas through the semiconductor process chamber so that process gases are flushed out of the process chamber prior to subsequent process steps or wafer removal. This purge gas is directed out of the semiconductor process chamber through the exhaust conductance path similarly to process gases. The second type of purging involves directing pre-clean purge gases through the exhaust assembly in order to minimize the reactivity of the deposits. The pre-clean purge gases may, but need not necessarily, comprise the same gases as the post-process purge gases. When an apparatus has one exhaust conductance path, this second type of purging normally cannot be performed while the semiconductor process chamber is processing wafers because the pre-clean purge gases may disrupt the processing. Since the apparatus experiences downtime regardless of the design of the purging assembly, the pre-clean purge gases typically flow through the semiconductor process chamber.

FIG. 3 illustrates an embodiment of the present invention having additional advantages, comprising a processing apparatus 300. Because the process gases can be routed through any one of the at least two parallel exhaust assemblies 320, 330, an exhaust assembly not being used may be purged with pre-clean purge gases without impacting the throughput of apparatus 300. For example, the exhaust assembly 330 can be isolated using the valves 306 and 335 as described above. Process gases flowing from the semiconductor process chamber 302 may flow through the exhaust assembly 320, so the exhaust assembly 330 may be purged without impacting the processes occurring in the semiconductor process chamber 302.

Referring to FIG. 3, a pre-clean purge gas source 308 is in communication with exhaust assemblies 320 and 330 via the purge gas inlets 312 and 314, respectively. Preferably, the purge gas inlets 312, 314 are as close to the semiconductor process chamber 302 as the design allows. The pre-clean purge gas is preferably nitrogen gas. The pre-clean purge gas may also comprise other inert gases, for example helium and argon. In some embodiments, the pre-clean purge comprises a series of inert gases and reactive cleaning gases. The reactive cleaning gases are configured to remove at least a portion of the deposits on the exhaust assemblies and include species that are reactive with the deposits, for example hydrogen gas, hydrogen chloride, hydrogen fluoride, or any other reactive gas or solvent suitable for cleaning the deposits. After injecting a reactive cleaning gas, an inert gas can be injected to expel the reactive cleaning gas from the exhaust assembly 330. The flow of pre-clean purgees gas can be controlled with the valve 310.

The pre-clean purge gas source 308 may comprise a single type of gas, a combination of gases, or an apparatus suitable for emitting a series of different gases. Rather than a common pre-clean purge gas source 308 as illustrated, the exhaust assemblies 320, 330 may have different pre-clean purge gas sources. Furthermore, although a valve 310 such as a three-way valve is illustrated in FIG. 3, skilled artisans will recognize that there are numerous possible methods of controlling the flow of pre-clean purge gas through the apparatus, including those routing methods discussed above in reference to the valve designs for diverting process gases coming out of the semiconductor process chamber 201.

Referring again to FIG. 3, pre-clean purge gases entering the exhaust assembly 320 (since the components associated with the two shown exhaust assemblies are preferably the same, only exhaust assembly 320 is described in detail) flow through the flow rate adjustment valve assembly, including the coarse flow rate adjustment valve 321 and the fine flow rate adjustment valve 322, and the pressure control valve 323. There are multiple options for disposal of the pre-clean purge gas, several of which are depicted in FIG. 3.

In the illustrated embodiment, the apparatus can be configured so that the pre-clean purge gases flow through the exhaust assembly 320, the isolation valve 325, the pump 350, and the scrubber 370 while the process gases flow through the exhaust assembly 330, the isolation valve 335, the pump 350, and the scrubber 370. Skilled artisans will recognize that care is preferably taken to ensure that the pre-clean purge gases do not flow upstream through the exhaust assembly 330 to the semiconductor process chamber 302 in such an embodiment.

The apparatus 300 can also be configured such that the purge gas exits the exhaust assembly 320 at a purge gas outlet 324. As discussed above, care must be taken to prevent the pre-clean purge gases from traveling upstream to the process chamber 302. The purge gas outlets 324 and 334 mitigate the need for such care because the pre-clean purge gases are never in open communication with the exhaust assemblies 320 and 330, respectively, or the process chamber 302 (i.e., the pre-clean purge gas assembly and the isolated exhaust assembly is a closed system with respect to the process chamber 302 and the non-isolated exhaust assembly). The purge gas outlets 324 and 334 are preferably as close to the isolation valves 325 and 335, respectively, as the design allows. In this alternative, the pre-clean purge gases flow out of the purge gas outlet 324 and through the pump 327, and are directed by a valve 328. In one embodiment, the pre-clean purge gases are disposed of without scrubbing. This embodiment is preferable when the pre-clean purge gases do not require scrubbing, for example when the pre-clean purge gases are inert.

In yet another configuration of the apparatus 300, the pre-clean purge gases exit the exhaust assembly 320 at the purge gas outlet 324, flow through the pump 327, bypassing the isolation valve 325 and the pump 350, and are directed by the valve 328 to join the process gases flowing through the exhaust assembly 330 at a purge gas inlet 360. This embodiment is preferable when the pre-clean purge gases require scrubbing, but it is undesirable for the pump 350 to handle both the process gases from the exhaust assembly 330 and the pre-clean purge gases from the exhaust assembly 320.

In still another configuration of the apparatus 300, the pre-clean purge gases exit the exhaust assembly 320 at the purge gas outlet 324, flow through the pump 327, and flow through a scrubber 329. This embodiment is preferable when the purge gas requires scrubbing, but is better suited to go through the scrubber 329 than through the scrubber 370 due to flowrate, temperature, pressure, composition, or any other scrubber process variable. Additional considerations for whether to provide additional pumps 327, 337 and scrubbers 329, 339 include cost, convenience, uniformity, physical space available. It will be appreciated that the pumps 327 and 337 can be replaced by a single pump (i.e., outlets 324 and 334 lead to the same pump for pre-clean purge gas). It will also be understood that scrubbers 329 and 339 can be replaced by a single scrubber, downstream of the pumps 327, 337 or downstream of the aforementioned common pump.

Although at least four embodiments of a purge gas flow assembly for the present invention are apparent from FIG. 3, skilled artisans will recognize that there are other possible assemblies. For example, adding a path from the valve 328 to the valve 338 would allow the pre-clean purge gases to flow through the exhaust assembly 320, through the pump 327, and then through the scrubber 339, as well as through the exhaust assembly 330, through the pump 337, and then through the scrubber 329. This type of modification would be appropriate if it is desirable to utilize either scrubber 329, 339 in conjunction with either exhaust assembly 320, 330, for example if the scrubbers 329, 339 required cleaning independent of the exhaust assemblies 320, 330. This type of modification would also be appropriate if the pre-clean purge gases comprise inert gases and reactive cleaning gases; the inert pre-clean purge gases could be directed to one scrubber 329 while the reactive cleaning gases could be directed to another scrubber 339. Furthermore, the purge gas assembly may comprise fewer than all of the described embodiments, for example only including the ability to direct purge gas through a separate pump and scrubber. Additionally, although FIG. 3 illustrates embodiments based on the apparatus 200 as depicted in FIG. 2A, a skilled artisan would recognize that a purge gas assembly may be similarly applied to all previously discussed embodiments with appropriate modifications.

Regardless of the configuration of the apparatus 300 or the disposal method of the pre-clean purge gases, the semiconductor process chamber 302 may continue to process workpieces during such pre-clean purging and cleaning, including post-process purges that are directed through the non-isolated exhaust assembly. This results in less downtime and higher throughput for the apparatus 300.

Another aspect of the present invention is the recognition that certain problems associated with cleaning an exhaust conductance path can be overcome by providing exhaust conductance paths in parallel. For example, the apparatus is safer because a cleaning operation may be conducted on one exhaust conductance path while the process gas is directed through another exhaust conductance path, to thereby decrease processing downtimes. This helps to resolve problems associated with skipped or truncated pre-clean purges and other cleaning operations because the cleaning duration no longer affects apparatus throughput. Full and thorough cleaning of the exhaust assemblies decreases the risk of flash and improves safety.

Although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. In addition, while several variations of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. It should be understood that various features and aspects of the disclosed embodiments can be combined with, or substituted for, one another in order to form varying modes of the disclosed invention. Thus, it is intended that the scope of the present invention herein disclosed should not be limited by the particular disclosed embodiments described above, but should be determined only by a fair reading of the claims that follow.

What is claimed is:

1. An apparatus for semiconductor processing comprising:
a semiconductor process chamber;
a first exhaust assembly in communication with and downstream of the semiconductor process chamber; and
a second exhaust assembly in communication with and downstream of the semiconductor process chamber and in parallel with the first exhaust assembly.

2. The apparatus of claim 1, further comprising:
a pump in communication with and downstream of the first exhaust assembly and the second exhaust assembly; and
a scrubber in communication with the pump.

3. The apparatus of claim 1, further comprising:
a first pump in communication with and downstream of the first exhaust assembly;
a second pump in communication with and downstream of the second exhaust assembly; and
a scrubber in communication with and downstream of the first pump and the second pump.

4. The apparatus of claim 1, wherein at least one of the exhaust assemblies comprises a reduced pressure stack including a flow rate adjustment valve assembly, a pressure control valve, and an isolation valve, the flow rate adjustment valve assembly comprising a coarse flow rate adjustment valve and a fine flow rate adjustment valve in parallel with the coarse flow rate adjustment valve.

5. The apparatus of claim 4, wherein the reduced pressure stack further includes a trap.

6. The apparatus of claim 5, wherein the trap comprises a U-shaped condenser.

7. The apparatus of claim 1, further comprising a valve apparatus downstream of the semiconductor process chamber and upstream of the first and second exhaust assemblies, the valve apparatus being controllable to direct exhaust gases from the process chamber into a selected one of the exhaust assemblies.

8. The apparatus of claim 7, wherein the valve apparatus comprises a three-way valve.

9. The apparatus of claim 1, wherein each of the exhaust assemblies is disconnectable from the apparatus while at least one other exhaust assembly conveys exhaust gases from the semiconductor process chamber.

10. The apparatus of claim 1, wherein the semiconductor process chamber comprises a chemical vapor deposition chamber.

11. The apparatus of claim 1, further comprising a purge gas assembly controllable to direct a purge gas into one or more of the exhaust assemblies and not into the process chamber.

12. The apparatus of claim 11, wherein the purge gas comprises an inert gas.

13. The apparatus of claim 11, wherein the purge gas comprises an inert gas and a reactive cleaning gas in series.

14. The apparatus of claim 11, wherein the purge gas assembly comprises a purge gas source adapted to direct the purge gas into a first purge gas inlet of the first exhaust assembly, the first exhaust assembly including a first purge gas outlet downstream of the first purge gas inlet.

15. The apparatus of claim 14, wherein the purge gas source is adapted to direct the purge gas into a second purge gas inlet of the second exhaust assembly, the second exhaust assembly including a second purge gas outlet downstream of the second purge gas inlet.

16. The apparatus of claim 11, wherein the purge gas assembly further comprises a purge gas pump.

17. The apparatus of claim 11, wherein the purge gas assembly further comprises a purge gas scrubber.

18. A method of processing workpieces in a process chamber, comprising:
flowing a process gas into the process chamber;
enabling the process gas to exit the process chamber and enter and flow through a first exhaust assembly for a first duration, the first exhaust assembly being in communication with and downstream of the process chamber;
preventing the process gas from entering and flowing through a second exhaust assembly during the first duration, the second exhaust assembly being in communication with and downstream of the process chamber and in parallel with the first exhaust assembly;
during a second duration after the first duration, preventing the process gas from entering and flowing through the first exhaust assembly; and
during the second duration, enabling the process gas to exit the process chamber and enter and flow through the second exhaust assembly.

19. The method of claim 18, further comprising:
flowing the process gas through a pump in communication with and downstream of the first assembly and second exhaust assemblies; and
flowing the process gas through a scrubber in communication with and downstream of the pump.

20. The method of claim 18, further comprising:
flowing the process gas through a first pump in communication with and downstream of the first exhaust assembly during the first duration;
flowing the process gas through a second pump in communication with and downstream of the second exhaust assembly during the second duration; and
flowing the process gas through a scrubber in communication with the first pump and the second pump.

21. The method of claim 18, further comprising disconnecting at least a portion of the first exhaust assembly from the process chamber during the second duration.

22. The method of claim 21, further comprising:
cleaning the disconnected portion of the first exhaust assembly during the second duration; and
after cleaning the disconnected portion, reconnecting the disconnected portion of the first exhaust assembly to the process chamber during the second duration.

23. The method of claim 18, wherein the process chamber comprises a semiconductor deposition chamber and the process gas comprises compounds used for epitaxial growth.

24. The method of claim 18, wherein the first duration is at least 150 hours.

25. The method of claim 18, wherein the first duration is at least 200 hours.

26. The method of claim 18, further comprising directing a purge gas through the first exhaust assembly but not through the second exhaust assembly during the second duration.

27. The method of claim 26, wherein the purge gas comprises nitrogen gas.

28. The method of claim 18, further comprising directing a reactive cleaning gas through the first exhaust assembly but not through the second exhaust assembly during the second duration, the cleaning gas configured to remove deposited materials from surfaces of the first exhaust assembly.

29. The method of claim 26, further comprising disconnecting at least a portion of the first exhaust assembly from the process chamber while the process gas is prevented from flowing from the process chamber through the first exhaust assembly during the second duration and after the purge gas has flowed through the first exhaust assembly.

30. The method of claim 29, further comprising:
cleaning the disconnected portion of the first exhaust assembly during the second duration; and
after cleaning the disconnected portion, reconnecting the disconnected portion of the first exhaust assembly to the process chamber during the second duration.

31. The method of claim 26, further comprising directing the purge gas through a purge gas pump in communication with and downstream of the first exhaust assembly during the second duration.

32. The method of claim 26, further comprising directing the purge gas through a purge gas scrubber in communication with and downstream of the first exhaust assembly.
